(19) United States
(12) Patent Application Publication
(10) Pub. No.: US 2026/0282967 A1
(43) Pub. Date: Sep. 17, 2026

(54) SUBSTRATE STRUCTURE

(71) Applicant: Unimicron Technology Corp., Taoyuan City (TW)

(72) Inventors: Tzyy-Jang Tseng, Taoyuan City (TW); Chin-Sheng Wang, Taoyuan City (TW); Ra-Min Tain, Hsinchu County (TW); Cheng-Ta Ko, Taipei City (TW); Pu-Ju Lin, Hsinchu City (TW); Guang-Hwa Ma, Hsinchu City (TW)

(73) Assignee: Unimicron Technology Corp., Taoyuan City (TW)

(21) Appl. No.: 19/269,044

(22) Filed: Jul. 15, 2025

Related U.S. Application Data
(60) Provisional application No. 63/770,328, filed on Mar. 11, 2025.

(30) Foreign Application Priority Data
Jun. 18, 2025 (TW) 114122773

(51) Int. Cl. H01L 23/498; H05K 1/02; H05K 1/11

(52) U.S. Cl. CPC H10W 70/65; H05K 1/0271; H05K 1/115; H10W 70/635

(57) ABSTRACT

A substrate structure including a first circuit portion, a second circuit portion, and a third circuit portion. The first circuit portion includes a first dielectric layer having a first Young's modulus. The second circuit portion includes a second dielectric layer having a second Young's modulus. The third circuit portion includes a third dielectric layer having a third Young's modulus. The second circuit portion is disposed between the first circuit portion and the third circuit portion, all of which are electrically connected to each other. The first Young's modulus is greater than the second Young's modulus and the third Young's modulus, and the second Young's modulus is less than the third Young's modulus.

### CROSS-REFERENCE TO RELATED APPLICATION

This application claims the priority benefit of U.S. provisional application Ser. No. 63/770,328, filed on Mar. 11, 2025 and Taiwan application serial no. 114122773, filed on Jun. 18, 2025. The entirety of each of the above-mentioned patent applications is hereby incorporated by reference herein and made a part of this specification.

### BACKGROUND

### Technical Field

The disclosure relates to a substrate structure.

### Description of Related Art

With the advancement of chip miniaturization technology, advanced packaging also requires a corresponding substrate structure capable of carrying more elements (for example, an IC carrier board with larger size and greater thickness). However, the warpage during the fabrication of additional circuit layers on the above substrate structure becomes more significant, thereby greatly reducing product reliability.

### SUMMARY

The disclosure provides a substrate structure, which improves warpage and further enhances product reliability.

A substrate structure of the disclosure includes a first circuit portion, a second circuit portion, and a third circuit portion. The first circuit portion includes a first dielectric layer having a first Young's modulus. The second circuit portion includes a second dielectric layer having a second Young's modulus. The third circuit portion includes a third dielectric layer having a third Young's modulus. The second circuit portion is disposed between the first circuit portion and the third circuit portion, all of which are electrically connected to each other. The first Young's modulus is greater than the second Young's modulus and the third Young's modulus, and the second Young's modulus is less than the third Young's modulus.

Based on the above, in the substrate structure of the disclosure, the dielectric layers in different circuit portions differentially designed in terms of the Young's modulus, so that the circuit portion clamped in the middle may relieve the stress generated during the manufacturing process by the adjacent circuit portions, thereby improving the warpage issue and further enhancing product reliability.

To make the features and advantages of the disclosure more comprehensible, several embodiments accompanied with drawings are described in detail as follows.

### BRIEF DESCRIPTION OF THE DRAWINGS

FIG. 1 is a schematic cross-sectional view of a substrate structure according to an embodiment of the disclosure.

FIGS. 2 to 5 are partial schematic cross-sectional views of the substrate structure in FIG. 1 during different stages of a manufacturing process.

FIG. 6 is a schematic cross-sectional view of a substrate structure according to another embodiment of the disclosure.

### DESCRIPTION OF THE EMBODIMENTS

In the following detailed description, exemplary embodiments disclosing specific details are set forth for purposes of illustration and not limitation, so as to provide a thorough understanding of various principles of the disclosure. However, it will be apparent to a person having ordinary skill in the art that the disclosure may be practiced in other embodiments without departing from the specific details disclosed herein. In addition, descriptions of well-known devices, methods, and materials are omitted so as not to obscure the description of various principles of the disclosure.

References are made to the drawings of this embodiment to describe the disclosure more comprehensively. However, the disclosure may also be embodied in various different forms and should not be limited to the embodiments described herein. The thickness, dimension, or size of layers or regions in the drawings may be exaggerated for clarity. The same or similar reference numerals denote the same or similar elements, and the following paragraphs will not redundantly describe them one by one.

The above and other technical contents, features, and effects of the disclosure may be clearly presented in the following detailed descriptions of the embodiments with reference to the drawings. Directional terms mentioned in the following embodiments, such as “upper,” “lower,” “top,” “bottom,” “left,” “right,” and the like, are merely based on the directions shown in the attached drawings. Therefore, the directional terms used are for illustration and not for limiting the disclosure.

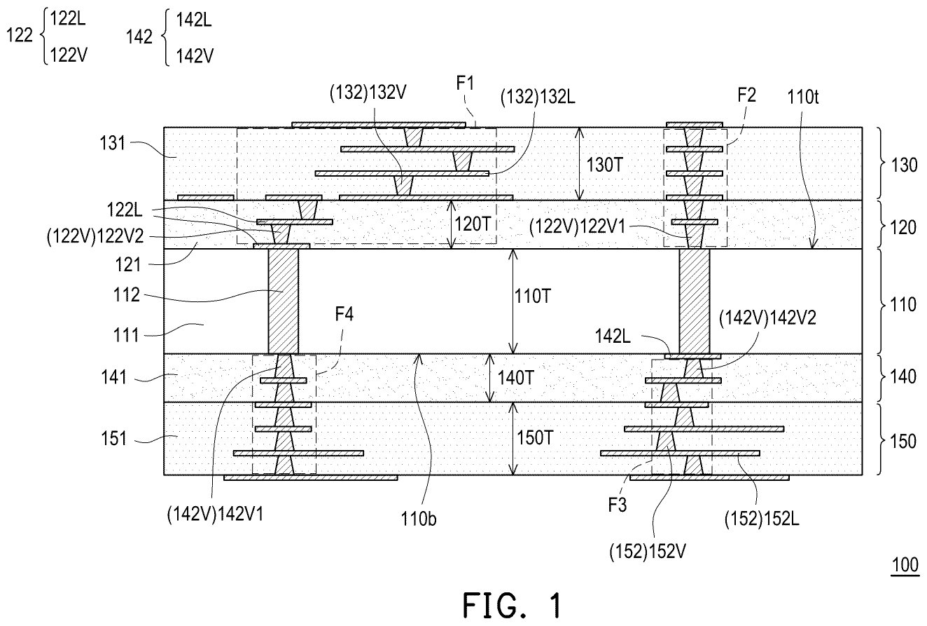

Referring to FIG. 1, in this embodiment, a substrate structure 100 at least includes a first circuit portion 110, a second circuit portion 120, and a third circuit portion 130, wherein the second circuit portion 120 is disposed between the first circuit portion 110 and the third circuit portion 130, all of which are electrically connected to each other. Further, the first circuit portion 110 includes a first dielectric layer 111 and a first conductive pattern 112 embedded in (for example, penetrating through) the first dielectric layer 111, the second circuit portion 120 includes a second dielectric layer 121 and a second conductive pattern 122 embedded in the second dielectric layer 121, and the third circuit portion 130 includes a third dielectric layer 131 and a third conductive pattern 132 embedded in the third dielectric layer 131.

In this embodiment, the dielectric layers in the above different circuit portions are differentially designed in terms of the Young's modulus. For example, the Young's modulus of the first dielectric layer 111 in the first circuit portion 110 may be greater than the Young's modulus of the second dielectric layer 121 in the second circuit portion 120 and the Young's modulus of the third dielectric layer 131 in the third circuit portion 130, and the Young's modulus of the second dielectric layer 121 in the second circuit portion 120 is less than the Young's modulus of the third dielectric layer 131 in the third circuit portion 130. In this way, since the second circuit portion 120 clamped in the middle has a lower Young's modulus, the second circuit portion 120 has a softer and more deformable property, and therefore may relieve the stress generated during the manufacturing process between the adjacent first circuit portion 110 and the third circuit portion 130 due to temperature changes (for example, mismatch of coefficients of thermal expansion (CTE) among the different dielectric materials of the three portions or between the dielectric materials and the conductive materials), so as to improve the warpage issue and enhance product reliability.

In some embodiments, the first dielectric layer 111 includes an inorganic material, and the second dielectric layer 121 and the third dielectric layer 131 include different organic materials. Therefore, an interface may be provided between the second circuit portion 120 and the third circuit portion 130. For example, in order to improve surface flatness to meet the demand for high-density circuits, the first dielectric layer 111 may be glass (therefore the first conductive pattern 112 may be a through-glass via (TGV)). However, due to the brittleness of glass, glass is more prone to cracking, and once cracked, the crack spreads rapidly. Therefore, correspondingly, the second dielectric layer 121 may be a photo-imageable dielectric (PID) material, and the third dielectric layer 131 may be an Ajinomoto build-up film (ABF) resin. By designing the photo-imageable dielectric material having a lower Young's modulus near the glass, and designing the ABF resin having a higher Young's modulus away from the glass, cracking may be effectively mitigated, so that the substrate structure 100 of this embodiment has better product competitiveness. However, the disclosure is not limited thereto. The first dielectric layer 111 may also be ceramic or other organic materials, and the second dielectric layer 121 and the third dielectric layer 131 may also be polypropylene (PP), FR4, prepreg, resin doped with organic fillers, or inorganic materials. As long as the dielectric layers are differentially designed in terms of the Young's modulus as in this embodiment, all of which fall within the scope of protection of the disclosure. Here, the Young's modulus of glass is between 51 GPa and 77 GPa, the Young's modulus of the photo-imageable dielectric material is between 1.6 GPa and 3.5 GPa, and the Young's modulus of the ABF resin is between 7.5 GPa and 20 GPa.

In some embodiments, when the first dielectric layer 111 is glass, the thickness design also has a significant influence on the performance of the substrate structure 100. For example, if the first dielectric layer 111 is to have structural strength to significantly reduce glass cracking, the first circuit portion 110 is preferably designed to have a certain thickness (such as a first thickness 110T of the first circuit portion 110 being greater than 50 micrometers). However, if the thickness of the first dielectric layer 111 is too large, it will cause the line spacing to increase, which is unfavorable for the applications of high-end products (such as ball grid array (BGA) packaging or chiplet), and due to the excessive aspect ratio (such as greater than 5), it also easily increases the difficulty of via filling by electroplating (such as copper filling or the like). At the same time, it also causes difficulty in separation by dicing (such as using laser processing or the like). Therefore, the first circuit portion 110 is preferably also controlled within a certain thickness range (such as the first thickness 110T of the first circuit portion 110 being less than 1300 micrometers). On the other hand, a second thickness 120T of the second circuit portion 120 may be less than a third thickness 130T of the third circuit portion 130. However, the disclosure is not limited thereto. In embodiments not shown, according to actual design requirements, the second thickness 120T of the second circuit portion 120 may be equal to or greater than the third thickness 130T of the third circuit portion 130. In some embodiments, the first thickness 110T of the first circuit portion 110 is greater than the second thickness 120T of the second circuit portion 120 and the third thickness 130T of the third circuit portion 130, and the second dielectric layer 121 may be composed of one to six film layers (with a single layer thickness of about 10 micrometers), and the third dielectric layer 131 may be composed of three to twelve film layers (with a single layer thickness of about 15 micrometers), but the disclosure is not limited thereto.

In some embodiments, the second conductive pattern 122 includes a plurality of conductive vias 122V and a plurality of conductive lines 122L, and the third conductive pattern 132 includes a plurality of conductive vias 132V and a plurality of conductive lines 132L, wherein the plurality of conductive vias 122V, the plurality of conductive lines 122L, the plurality of conductive vias 132V, and the plurality of conductive lines 132L may be partially or entirely electrically connected in series. On the other hand, in a first region of the substrate structure 100 (such as the location of an upper left frame F1 in FIG. 1), a part of the conductive vias 122V and a part of the conductive vias 132V may be disposed in a staggered manner. For example, in the aforementioned first region, the orthographic projections of the conductive vias 122V and the conductive vias 132V of adjacent film layers on the first circuit portion 110 do not overlap. Through such configuration, vertical stress accumulation may be effectively reduced, thereby further enhancing product reliability. However, the disclosure is not limited thereto. In a second region of the substrate structure 100 (such as the location of an upper right frame F2 in FIG. 1), another part of the conductive vias 122V and another part of the conductive vias 132V may be disposed in alignment. For example, in the aforementioned second region, the orthographic projections of another part of the conductive vias 122V and another part of the conductive vias 132V of adjacent film layers on the first circuit portion 110 overlap. In some embodiments, the plurality of conductive vias 122V themselves may also be disposed in a staggered or aligned configuration similar to the above, and the plurality of conductive vias 132V themselves may also be disposed in a staggered or aligned configuration similar to the above.

In some embodiments, a conductive via 122V (such as a conductive via 122V1) in the second conductive pattern 122 that is closest to the first circuit portion 110 lands on the first circuit portion 110. In this way, the stress caused at a corner due to landing on a conductive line (such as a pad below another conductive via 122V2) may be omitted. Based on this, the layout density of the circuit may also be improved. However, the disclosure is not limited thereto, so the other conductive via 122V2 may still be disposed on the conductive line 122L.

In some embodiments, the second circuit portion 120 has two opposite surfaces respectively in direct contact with the first circuit portion 110 and the third circuit portion 130, and an edge of the second circuit portion 120 is aligned with an edge of the first circuit portion 110. That is, the second circuit portion 120 does not extend to cover a sidewall of the first circuit portion 110. However, the disclosure is not limited thereto.

In this embodiment, the substrate structure 100 may have a symmetrical design. That is, the substrate structure 100 further includes a fourth circuit portion 140 and a fifth circuit portion 150, wherein the fourth circuit portion 140 is disposed between the first circuit portion 110 and the fifth circuit portion 150, all of which are electrically connected to each other. Further, the second circuit portion 120 and the third circuit portion 130 may be disposed on a first surface 110t of the first circuit portion 110, and the fourth circuit portion 140 and the fifth circuit portion 150 may be disposed on a second surface 110b of the first circuit portion 110 opposite to the first surface 110t. In this way, the first circuit portion 110 may be regarded as a core portion of the substrate structure 100, the second circuit portion 120 and the third circuit portion 130 may be regarded as a top build-up portion of the substrate structure 100, and the fourth circuit portion 140 and the fifth circuit portion 150 may be regarded as a bottom build-up portion of the substrate structure 100.

In some embodiments, the fourth circuit portion 140 and the fifth circuit portion 150 may adopt a design similar to that of the second circuit portion 120 and the third circuit portion 130. The following will further describe this. For simplicity, only the configuration relationship between the components will be described below, and other details (such as effects, etc.) not specifically described may be correspondingly referred to the above paragraphs having similar configuration relationships and will not be redundantly described below.

In some embodiments, the fourth circuit portion 140 includes a fourth dielectric layer 141 and a fourth conductive pattern 142 embedded in the fourth dielectric layer 141, and the fifth circuit portion 150 includes a fifth dielectric layer 151 and a third conductive pattern 152 embedded in the fifth dielectric layer 151, wherein the differentiated design of Young's modulus may be that a first Young's modulus of the first dielectric layer 111 is greater than a fourth Young's modulus of the fourth dielectric layer 141 and a fifth Young's modulus of the fifth dielectric layer 151, and the fourth Young's modulus of the fourth dielectric layer 141 is less than the fifth Young's modulus of the fifth dielectric layer 151.

In some embodiments, the fourth dielectric layer 141 and the fifth dielectric layer 151 include different organic materials. Therefore, an interface may be provided between the fourth circuit portion 140 and the fifth circuit portion 150. In some embodiments, a material of the second dielectric layer 121 and a material of the fourth dielectric layer 141 may be the same, and a material of the third dielectric layer 131 and a material of the fifth dielectric layer 151 may be the same. For example, when the first dielectric layer 111 is glass, the second dielectric layer 121 and the fourth dielectric layer 141 may both be photo-imageable dielectric materials, and the third dielectric layer 131 and the fifth dielectric layer 151 may both be ABF resin. However, the disclosure is not limited thereto. In other embodiments, the material of the second dielectric layer 121 and the material of the fourth dielectric layer 141 may be different, and the material of the third dielectric layer 131 and the material of the fifth dielectric layer 151 may be different.

In some embodiments, a fourth thickness 140T of the fourth circuit portion 140 may be less than a fifth thickness 150T of the fifth circuit portion 150. However, the disclosure is not limited thereto. In embodiments not shown, the fourth thickness 140T of the fourth circuit portion 140 may be equal to or greater than the fifth thickness 150T of the fifth circuit portion 150. In some embodiments, the thickness of the second circuit portion 120 and the thickness of the fourth circuit portion 140 may be the same (for example, may be composed of one to six film layers), and the thickness of the third circuit portion 130 and the thickness of the fifth circuit portion 150 may be the same (for example, may be composed of three to twelve film layers). However, the disclosure is not limited thereto. In other embodiments, the thickness of the second circuit portion 120 and the thickness of the fourth circuit portion 140 may be different, and the thickness of the third circuit portion 130 and the thickness of the fifth circuit portion 150 may be different.

In some embodiments, the fourth conductive pattern 142 includes a plurality of conductive vias 142V and a plurality of conductive lines 142L, the fifth conductive pattern 152 includes a plurality of conductive vias 152V and a plurality of conductive lines 152L, and in a third region of the substrate structure 100 (such as the location of a lower right frame F3), a part of the conductive vias 142V and a part of the conductive vias 152V may be disposed in a staggered manner. However, the disclosure is not limited thereto. In a fourth region of the substrate structure 100 (such as the location of a lower left frame F4), another part of the conductive vias 142V and another part of the conductive vias 152V may be disposed in alignment. In some embodiments, the plurality of conductive vias 142V themselves may also be disposed in a similar staggered or aligned configuration, and the plurality of conductive vias 152V themselves may also be disposed in a similar staggered or aligned configuration.

In some embodiments, a conductive via 142V (such as a conductive via 142V1) in the fourth conductive pattern 142 that is closest to the first circuit portion 110 lands on the first circuit portion 110. However, the disclosure is not limited thereto, so another conductive via 142V2 may still be disposed on the conductive line 142L.

In some embodiments, the fourth circuit portion 140 has two opposite surfaces respectively in direct contact with the first circuit portion 110 and the fifth circuit portion 150, and an edge of the fourth circuit portion 140 is aligned with an edge of the first circuit portion 110. That is, the fourth circuit portion 140 does not extend to cover a sidewall of the first circuit portion 110. However, the disclosure is not limited thereto.

The manufacturing process of the above substrate structure 100 will be described below with drawings. However, it should be stated that the substrate structure 100 of the disclosure is not limited to being manufactured in this way. Other suitable build-up methods may also be adopted. As long as a substrate structure has a differentiated design in terms of Young's modulus of the dielectric layers between different circuit portions as in the disclosure, the substrate structure falls within the scope of protection of the disclosure.

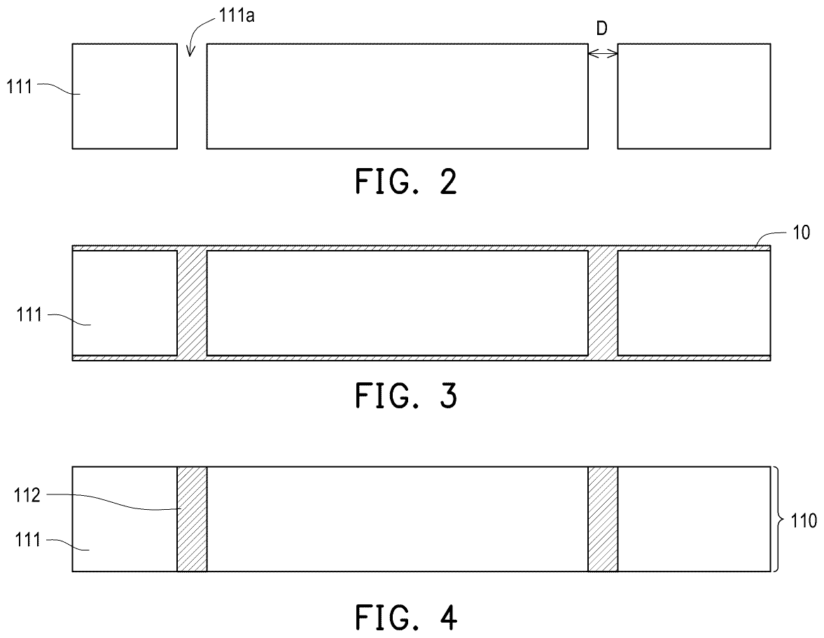

Referring to FIG. 2, a first dielectric layer 111 is provided, and a plurality of openings 111a are formed by a suitable method (such as laser drilling or the like), wherein a diameter D of each opening 111a is, for example, between 10 micrometers and 200 micrometers, and a surface roughness of the first dielectric layer 111 is, for example, less than 10 nanometers. However, the disclosure is not limited thereto. The diameter D of each opening 111a and the surface roughness of the first dielectric layer 111 may also be other suitable values.

Referring to FIG. 3, a conductive material 10 (for example, copper or the like) is comprehensively formed in the plurality of openings 111a and on an opposite surface of the first dielectric layer 111 by a suitable method (such as electroplating or the like).

Referring to FIG. 4, the conductive material 10 on the opposite surface of the first dielectric layer 111 is removed by a suitable method (such as a chemical mechanical polishing (CMP) process or the like) to form a first conductive pattern 112 in the first circuit portion 110.

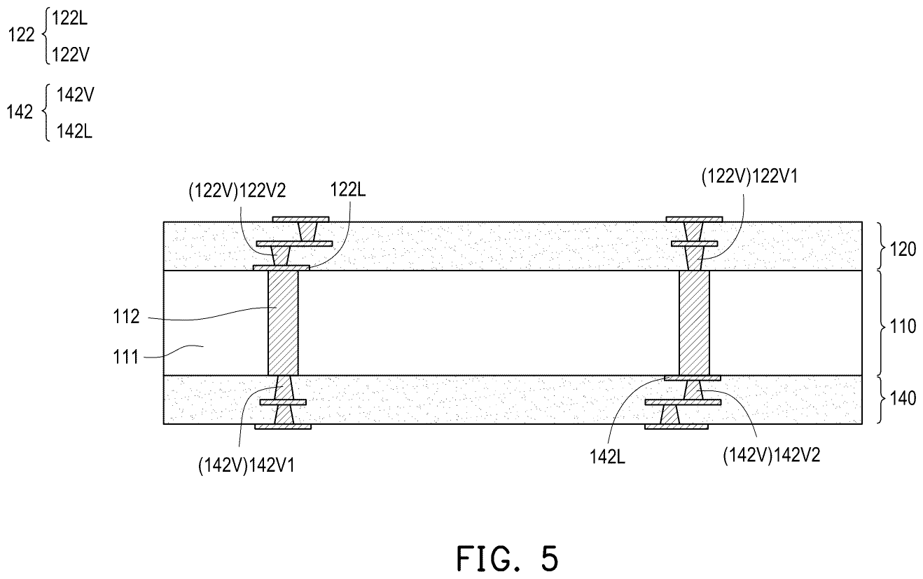

Referring to FIG. 5, a second circuit portion 120 and a fourth circuit portion 140 are formed on the opposite surface of the first dielectric layer 111. Next, a third circuit portion 130 and a fifth circuit portion 150 may be respectively formed on the second circuit portion 120 and the fourth circuit portion 140, so as to complete the substrate structure 100 in FIG. 1. Among them, based on material selection, the conductive vias 122V and the conductive vias 142V in the second circuit portion 120 and the fourth circuit portion 140 may be formed by photolithography or the like, and the conductive vias 132V and the conductive vias 152V in the third circuit portion 130 and the fifth circuit portion 150 may be formed by laser drilling or the like.

It must be stated here that the following embodiments continue to use the element reference numerals and part of the content of the above embodiments, in which the same or similar reference numerals are used to denote the same or similar elements, and the description of the same technical content is omitted. The description of the omitted part may be referred to the above embodiments, and the following embodiments will not be redundantly repeated.

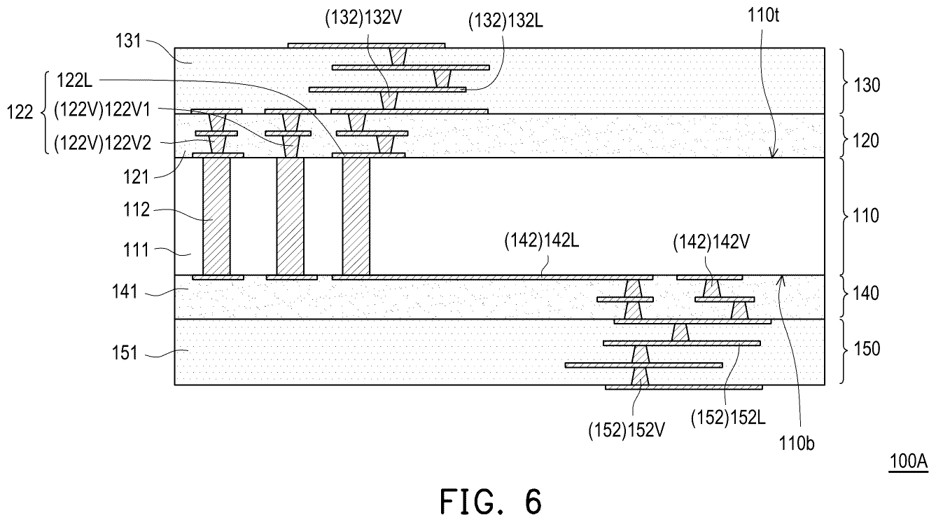

Please refer to FIG. 6, which is similar to FIG. 1. The difference lies in that the bottom build-up portion of a substrate structure 100A may be disposed in a staggered configuration with the core portion and the top build-up portion. For example, a part of the fourth conductive pattern 142 and a part of the fifth conductive pattern 152 do not underlie the first conductive pattern 112, the second conductive pattern 122, and the third conductive pattern 132, so as to further reduce stress accumulation. However, the disclosure is not limited thereto.

It should be stated that, according to actual design requirements, the above substrate structure may be symmetrical or asymmetrical. Whether it is symmetrical may be based on the core portion, that is, whether both sides have build-up portions and/or whether the build-up portions on both sides are the same or different in the design of material, thickness, conductive pattern, and so on. However, whether symmetrical or asymmetrical, as long as the substrate structure includes at least three circuit portions and the dielectric layers in those circuit portions have a differentiated design in terms of the Young's modulus, it falls within the scope of protection of the disclosure. In addition, the above designation method is merely for clear explanation. Other designation methods may also be adopted. For example, the above circuit portion 120 and circuit portion 130 may also be designated as a fourth circuit portion and a fifth circuit portion. In this case, the circuit portion 140 and the circuit portion 150 may also be designated as a second circuit portion and a third circuit portion, and the components in those circuit portions may also be correspondingly adjusted according to their designations as “second,” “third,” “fourth,” and “fifth.”

In summary, the substrate structure of the disclosure performs a differentiated design on the dielectric layers in different circuit portions in terms of the Young's modulus, so that the circuit portion clamped in the middle may relieve the stress generated during the manufacturing process by the adjacent circuit portions, so as to improve the warpage issue and further enhance product reliability.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A substrate structure, comprising:
a first circuit portion, comprising a first dielectric layer having a first Young's modulus;
a second circuit portion, comprising a second dielectric layer having a second Young's modulus; and
a third circuit portion, comprising a third dielectric layer having a third Young's modulus, wherein the second circuit portion is disposed between the first circuit portion and the third circuit portion, all of which are electrically connected to each other, the first Young's modulus is greater than the second Young's modulus and the third Young's modulus, and the second Young's modulus is less than the third Young's modulus.

2. The substrate structure according to claim 1, wherein the first dielectric layer comprises an inorganic material.

3. The substrate structure according to claim 1, wherein the second dielectric layer and the third dielectric layer comprise different organic materials.

4. The substrate structure according to claim 1, wherein a thickness of the second circuit portion is less than a thickness of the third circuit portion.

5. The substrate structure according to claim 1, wherein an interface is provided between the second circuit portion and the third circuit portion.

6. The substrate structure according to claim 1, wherein the second circuit portion further comprises a second conductive pattern embedded in the second dielectric layer, and the third circuit portion further comprises a third conductive pattern embedded in the third dielectric layer, wherein:
a part of a plurality of conductive vias in the second conductive pattern and a part of a plurality of conductive vias in the third conductive pattern are disposed in a staggered manner;
the plurality of conductive vias in the second conductive pattern are disposed in a staggered manner; and/or
the plurality of conductive vias in the third conductive pattern are disposed in a staggered manner.

7. The substrate structure according to claim 6, wherein the conductive via in the second conductive pattern closest to the first circuit portion lands on the first circuit portion.

8. The substrate structure according to claim 1, wherein the first circuit portion further comprises a first conductive pattern penetrating the first dielectric layer.

9. The substrate structure according to claim 1, wherein an edge of the second circuit portion is aligned with an edge of the first circuit portion.

10. The substrate structure according to claim 1, further comprising:
a fourth circuit portion, comprising a fourth dielectric layer having a fourth Young's modulus; and
a fifth circuit portion, comprising a fifth dielectric layer having a fifth Young's modulus, wherein the fourth circuit portion is disposed between the first circuit portion and the fifth circuit portion, all of which are electrically connected to each other, the first Young's modulus is greater than the fourth Young's modulus and the fifth Young's modulus, and the fourth Young's modulus is less than the fifth Young's modulus.

11. The substrate structure according to claim 10, wherein the second circuit portion and the third circuit portion are disposed on a first surface of the first circuit portion, and the fourth circuit portion and the fifth circuit portion are disposed on a second surface of the first circuit portion opposite to the first surface.

12. The substrate structure according to claim 10, wherein the fourth dielectric layer and the fifth dielectric layer comprise different organic materials.

13. The substrate structure according to claim 10, wherein a thickness of the fourth circuit portion is less than a thickness of the fifth circuit portion.

14. The substrate structure according to claim 10, wherein an edge of the fourth circuit portion is aligned with an edge of the first circuit portion.

15. The substrate structure according to claim 10, wherein an interface is provided between the fourth circuit portion and the fifth circuit portion.

16. The substrate structure according to claim 10, wherein the fourth circuit portion further comprises a fourth conductive pattern embedded in the fourth dielectric layer, and the fifth circuit portion further comprises a fifth conductive pattern embedded in the fifth dielectric layer, wherein:
a part of a plurality of conductive vias in the fourth conductive pattern and a part of a plurality of conductive vias in the fifth conductive pattern are disposed in a staggered manner;
the plurality of conductive vias in the fourth conductive pattern are disposed in a staggered manner; and/or
the plurality of conductive vias in the fifth conductive pattern are disposed in a staggered manner.

17. The substrate structure according to claim 16, wherein the conductive via in the fourth conductive pattern closest to the first circuit portion lands on the first circuit portion.

18. The substrate structure according to claim 16, wherein the first circuit portion further comprises a first conductive pattern penetrating the first dielectric layer, and the fourth conductive pattern and the first conductive pattern are disposed in a staggered manner.

19. The substrate structure according to claim 10, wherein the second dielectric layer and the fourth dielectric layer have a same material, and the third dielectric layer and the fifth dielectric layer have a same material.

20. The substrate structure according to claim 10, wherein the second circuit portion and the fourth circuit portion have a same thickness, and the third circuit portion and the fifth circuit portion a same thickness.
